(19) United States
(12) Patent Application Publication
(10) Pub. No.: US 2005/0124121 A1
(43) Pub. Date: Jun. 9, 2005

(54) Anneal of high-k dielectric using NH3 and an oxidizer

(76) Inventors: Antonio L.P. Rotondaro, Dallas, TX (US); James J. Chambers, Dallas, TX (US); Mark R. Visokay, Richardson, TX (US); Luigi Colombo, Dallas, TX (US)

Correspondence Address: TEXAS INSTRUMENTS INCORPORATED, P O BOX 655474, M/S 3999, DALLAS, TX, 75265, US

(21) Appl. No.: 10/731,647

(22) Filed: Dec. 9, 2003

(51) Int. Cl. H01L 21/336; H01L 21/8242; H01L 21/31; H01L 21/4763

(52) U.S. Cl. 438/287; 438/785; 438/261; 438/240; 438/591

(57) ABSTRACT

The present invention pertains to annealing a high dielectric constant (high-k) material in a manner that substantially reduces or eliminates disadvantages and problems heretofore associated with the same. In particular, the high-k material is annealed in an ambient having a single chemistry of nitrogen and hydrogen, such as ammonia (NH₃), to nitride and react unwanted impurities, and an oxidizer to oxidize and densify the high-k material, while mitigating growth of a lower-k material at an interface of the high-k material and an underlying substrate. Additionally, particular temperatures and pressures are utilized within the process so that the risk of an undesired exothermic reaction is mitigated. Annealing the high-k material in accordance with manners disclosed herein has application to semiconductor fabrication processes and, as such, is discussed herein within the context of the same.

### RELATED APPLICATIONS

This application is related to U.S. patent application Ser. No. 10/185,326, filed on Jun. 28, 2002, entitled ANNEAL SEQUENCE FOR HIGH-K FILM PROPERTY OPTIMIZATION; U.S. patent application Ser. No. 10/232,124, filed on Aug. 30, 2002, entitled GATE STRUCTURE AND METHOD; and U.S. Pat. No. 6,544,906, filed Oct. 25, 2001, entitled ANNEALING OF HIGH-K DIELECTRIC MATERIALS, wherein the entirety of these applications and patents are hereby incorporated by reference as if fully set forth herein.

### FIELD OF INVENTION

The present invention relates generally to semiconductor processing, and more particularly to annealing a material having a high dielectric constant.

### BACKGROUND OF THE INVENTION

Field effect transistors (FETs) are widely used in the electronics industry for switching, amplification, filtering, and/or other tasks related to both analog and digital electrical signals. Most common among these are metal-oxide-semiconductor field-effect transistors (MOSFETs), wherein a metal or (doped) polysilicon gate contact or electrode is energized to create an electric field in an underlying channel region of a semiconductor body, by which current is allowed to conduct between a source region and a drain region of the semiconductor body.

The source and drain regions are typically formed by adding dopants to targeted regions on either side of the channel region in a semiconductor substrate. A gate dielectric or gate oxide, such as silicon dioxide (SiO₂), is formed over the channel region to physically separate the gate electrode from the substrate, and more particularly the channel region. A patterned gate electrode and gate dielectric is commonly referred to as a gate structure or stack.

The gate dielectric has electrically insulative properties and, as such, serves to retard the flow of large electrical currents between the gate electrode and the source/drain regions or channel of the substrate when a voltage is applied to the gate contact. The gate dielectric also serves to allow the applied gate voltage to set up an electric field in the channel region in a controllable manner.

A continuing trend in the manufacture of semiconductor products is toward a steady reduction in the size of electrical devices (known as scaling), together with improvements in device performance in terms of device switching speed, power consumption, reliability, etc. New materials and processes have been developed and employed in silicon processing technology to accommodate these requirements, including the ability to pattern and etch smaller device features. Recently, however, electrical and physical limitations have been reached in the thickness of gate dielectrics, particularly those formed of silicon dioxide.

By way of example, FIG. 1A illustrates a conventional complementary metal oxide semiconductor (CMOS) device 2 with PMOS and NMOS type transistor devices 4 and 6, respectively, formed in or on a silicon substrate 8. Isolation structures 10, such as shallow trench (oxide) isolation structures (STI), are formed within the substrate 8 to electrically isolate the devices from one another as well as from other surrounding devices. For example, one or both of the transistors may be included as part of an integrated circuit or used in any other appropriate manner.

The substrate 8 in the above example is lightly doped p-type silicon with an n-well 12 formed therein under the PMOS transistor 4. The PMOS device 4 includes two laterally spaced p-doped source/drain regions 14a and 14b with a channel region 16 located therebetween in the n-well 12. A gate is formed over the channel region 16 comprising an SiO₂ gate dielectric 20 overlying the channel 16 and a conductive polysilicon gate contact structure 22 formed over the gate dielectric 20.

The NMOS device 6 includes two laterally spaced n-doped source/drain regions 24a and 24b outlying a channel region 26 in the substrate 8 (or alternatively a p-well region (not shown)) with a gate formed over the channel region 26 comprising an SiO₂ gate dielectric layer 30 and a polysilicon gate contact 32, where the gate dielectrics 20 and 30 may be patterned from the same oxide layer. Both the PMOS device 4 and the NMOS device 6 include sidewall spacers 18 that aid in doping the respective source/drain regions 14a, 14b and 24a, 24b.

Referring to the NMOS device 6, for example, the resistivity of the channel 26 may be controlled by the voltage applied to the gate contact 32, where changing the gate voltage changes the amount of current through channel 26. The gate contact 32 and the channel 26 are separated by the SiO₂ gate dielectric 30, which is an insulator. The gate dielectric, thus, allows little or no current to flow between the gate contact 32 and the channel 26. The gate dielectric 30 allows the gate voltage at the contact 32 to induce an electric field in the channel 26, by which the channel resistance can be controlled by the applied gate voltage.

MOSFET devices produce an output current proportional to the ratio of the width over the length of the channel, where the channel length is the physical distance between the source/drain regions (e.g., between regions 24a and 24b in the device 6) and the width runs perpendicular to the length (e.g., perpendicular to the page in FIG. 1A). Thus, scaling the NMOS device 6 to make the width narrower may reduce the device output current. Previously, this characteristic has been accommodated by decreasing the thickness of gate dielectric 30, thus bringing the gate contact 32 closer to the channel 26.

Additionally, the thickness and dielectric constant of the gate dielectric layer 30 are typically chosen to create a gate capacitance appropriate for a particular use of the transistor 6, where the gate capacitance, among other things, controls the formation of the electrical field in channel region 26. The gate capacitance is directly proportional to the dielectric constant of gate dielectric layer 30 and inversely proportional to the thickness of gate dielectric layer 30. Therefore, as the other features of transistor 6 are scaled down, the thickness of gate dielectric layer 30 may also be scaled down proportionally to maintain an appropriate gate capacitance (assuming the dielectric constant of the material remains the same).

However, making the gate dielectric layer 30 thinner can have undesirable results, particularly where the gate dielectric 30 is SiO₂. One shortcoming of a thin SiO₂ gate dielectric 30 is large leakage currents due to direct tunneling through the oxide 30. This problem is exacerbated by conventional limitations in the ability to deposit or grow such films with uniform thickness. Since the films are literally formed from a few layers of atoms (monolayers), very precise process controls are required to uniformly and repeatably produce the layers. Uniform coverage is important because device parameters may change dramatically based upon the presence or absence of even a single layer of dielectric material. Also, a thin SiO₂ gate dielectric layer 30 provides a poor diffusion barrier to dopants. In this manner, boron, for example, may be allowed to penetrate into and contaminate the underlying channel region 16 during formation of the source/drain regions 14a and 14b.

Consequently, recent efforts involving MOSFET device scaling have focused on alternative dielectric materials that can be made thicker than scaled silicon dioxide layers and yet still produce the same field effect performance. These materials are often referred to as high-k materials because their dielectric constants are greater than that of SiO₂ (which is about 3.9). The relative performance of such high-k materials is often expressed as equivalent oxide thickness (EOT), because, while the alternative layer may be thicker, it still provides the equivalent electrical effect of a much thinner layer of SiO₂.

Referring to FIG. 1B, one proposed alternative structure is illustrated, in which a high-k gate dielectric material 30a is used to form a gate dielectric layer 30′ in an NMOS device 6′. A conductive gate electrode structure 32′ is formed over the high-k dielectric layer 30a. However, the alternative gate dielectric materials explored thus far typically include metallic elements, and must be deposited, rather than being grown, over silicon substrates. Such high-k materials can be deposited utilizing chemical vapor deposition (CVD), atomic layer deposition (ALD), physical vapor deposition (PVD), plasma enhanced chemical vapor deposition (PECVD), and/or molecular beam epitaxy (MBE) techniques, for example.

Deposited films are often not stoichiometric and may have defects or impurities (e.g., unwanted —OH and/or —H) associated therewith that affect their electrical properties. Accordingly, such layers are commonly annealed in an attempt to remove some of these impurities and to densify and fully oxidize the layers. Nevertheless, since the high-k materials contain oxygen, and are deposited rather than grown, the upper surface of the silicon substrate 8 can oxidize to some extent during formation of the high-k dielectric material. In this manner, an interfacial region 30b between the substrate 8 and the high-k material 30a can have a dielectric constant (k) lower than that of the high-k dielectric layer 30a.

The presence of such an oxidized region 30b can lower the overall effective dielectric constant of the gate dielectric, leading to undesired results, such as high leakage currents, poor transistor reliability, etc. For example, such an oxidized area 30b generally has unsatisfied or dangling bonds that can act as interface charging centers which can degrade carrier mobility in the operation of the transistor 6′. Additionally, such a lower-k interfacial area 30b may also present issues related to, among other things, charge scattering, charge trapping, fixed charge, density of interface state (Dᵢₜ), reduction of bulk charge, interfacial charge, etc.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor to delineate the scope of the invention. Rather, its primary purpose is merely to present one or more concepts of the invention in a simplified form as a prelude to the more detailed description that is presented later.

The present invention pertains to annealing a high-k dielectric material with a single chemistry in a manner that allows the material to be oxidized that concurrently facilitates passivation of defects, removal of impurities and densification of the high-k dielectric. The anneal also does not promote the formation of a lower-k material at an interface of the high-k dielectric layer and an underlying substrate. The anneal can be performed at relatively low pressures and high temperatures to enhance densification and defect reduction while mitigating the interfacial growth of a low-k layer.

According to one or more aspects of the present invention, a method for annealing a layer of material having a high dielectric constant (high-k) is disclosed. The layer of high-k material is formed over a semiconductor substrate, and the method includes introducing an ambient comprising hydrogen, nitrogen and an oxidizer to the substrate and layer of high-k material, and heating the high-k dielectric layer to a temperature greater than 700 degrees Celsius while the gate dielectric layer is in the ambient. The ambient mitigates the formation of lower dielectric constant (lower-k) material between the high-k gate dielectric layer and the substrate.

According to one or more other aspects of the present invention, a method for annealing a high dielectric constant (high-k) gate dielectric layer is disclosed that includes placing a wafer having one or more partially formed transistors having respective high-k gate dielectric layers overlying a substrate in an ambient comprising hydrogen, nitrogen and an oxidizer. The method also includes heating the high-k gate dielectric layers to a temperature greater than 700 degrees Celsius while the layers are in the ambient. The ambient mitigates the formation of lower dielectric constant (lower-k) material between the respective high-k gate dielectric layers and the substrate.

In accordance with one or more other aspects of the present invention, a method for fabricating a transistor having a high dielectric constant (high-k) gate dielectric layer is disclosed. The method includes forming a high-k gate dielectric layer on a substrate, and annealing the substrate and high-k gate dielectric layer. The annealing includes introducing an ambient comprising hydrogen, nitrogen and an oxidizer to the substrate and high-k gate dielectric layer, and heating the high-k dielectric layer to a temperature greater than 700 degrees Celsius while the gate dielectric layer is in the ambient. The ambient mitigates the formation of lower dielectric constant (lower-k) material between the high-k gate dielectric layer and the substrate.

To the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings

### BRIEF DESCRIPTION OF THE DRAWINGS

FIG. 1A is a partial side elevation view in section illustrating a conventional semiconductor device with NMOS and PMOS transistors.

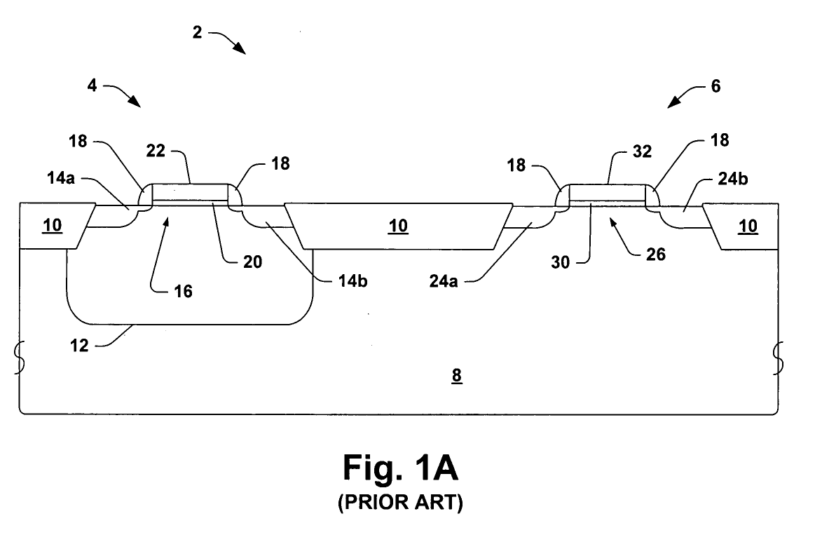

FIG. 1B is a partial side elevation view in section illustrating an unintended lower-k interfacial region in a proposed gate structure.

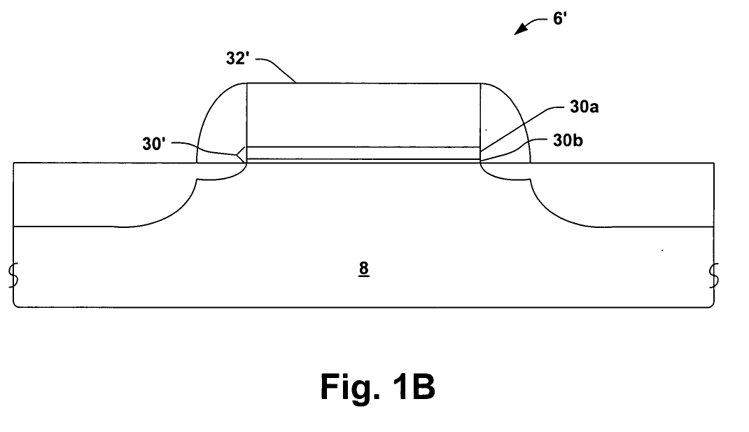

FIG. 2 is a flow diagram illustrating a method for annealing a high-k dielectric material in accordance with one or more aspects of the present invention.

FIG. 3 is a schematic block diagram illustrating an exemplary system wherein a high-k dielectric material can be annealed in accordance with one or more aspects of the present invention.

FIG. 4 is a schematic block diagram illustrating another exemplary system for annealing a high-k dielectric material in accordance with one or more aspects of the present invention.

### DETAILED DESCRIPTION OF THE INVENTION

One or more aspects of the present invention are described with reference to the drawings, wherein like reference numerals are generally utilized to refer to like elements throughout, and wherein the various structures are not necessarily drawn to scale. In the following description, for purposes of explanation, numerous specific details are set forth in order to provide a thorough understanding of one or more aspects of the present invention. It may be evident, however, that one or more aspects of the present invention may be practiced with a lesser degree of these specific details. In other instances, well-known structures and devices are shown in block diagram form in order to facilitate describing one or more aspects of the present invention.

The present invention pertains to annealing a high dielectric constant (high-k) material in a manner that substantially reduces or eliminates disadvantages and problems heretofore associated with the same. In particular, the high-k material is annealed in an ambient having a single chemistry of nitrogen and hydrogen, such as ammonia (NH₃), and an oxidizer to purify, oxidize and densify the high-k material, while mitigating growth of a lower-k material at an interface of the high-k material and an underlying substrate. Additionally, particular temperatures and pressures are utilized within the process so that the risk of said interfacial growth is minimized. Annealing the high-k material in accordance with manners disclosed herein has application to semiconductor fabrication processes and, as such, is discussed herein within the context of the same.

As discussed above, semiconductor devices, such as metal oxide semiconductor (MOS) transistors are formed upon a semiconductor substrate. Such a MOS transistor includes source and drain regions and a gate structure that includes a gate electrode and a gate dielectric layer. The gate dielectric layer physically separates the gate electrode from the substrate and prevents or attempts to prevent an electrical current from flowing between the gate electrode and the source/drain regions or substrate (and more specifically, a channel region underlying the gate structure and formed between the source/drain regions). Additionally, spacers may be located on either side of the gate structure to aid in establishing or doping the source/drain regions.

A terminal (typically a metal conductor) is generally connected to the gate electrode and respective terminals are also connected to the source region and the drain region. In operation, upon appropriate biasing at the source/drain regions, a input voltage is applied at the gate terminal to form an electrical field in the channel region. This electrical field may be varied by changing the input voltage. This variance in the electrical field can be used to modulate the conductance of the channel region and thus control the current flow between the source and drain regions.

As technology advances, the size of semiconductor devices, such as MOS transistors, continues to decrease as demand increases for more devices to be fabricated on a single silicon wafer and to operate faster and with less power. As the size of these devices continually decreases, the various features of the devices are also scaled down. For example, the decreasing size of transistors may create a need to decrease the thickness of the gate dielectric layer as well as other transistor elements. However, decreasing the gate dielectric thickness typically creates problems when traditional gate dielectric materials, such as silicon dioxide, are used.

By way of example, the thickness and dielectric constant of a gate dielectric layer are typically chosen to create a gate capacitance appropriate for a particular use of the transistor, where the gate capacitance, among other things, influences the formation of the electrical field in the channel region. The gate capacitance is directly proportional to the dielectric constant of the gate dielectric layer and inversely proportional to the thickness of the gate dielectric layer. Therefore, as the other features of the transistor are scaled down, the thickness of gate dielectric layer may also be scaled down proportionally to maintain an appropriate gate capacitance, among other things, (assuming the dielectric constant of the material remains the same). However, as thinner gate dielectric layers are used, the leakage current through gate dielectric layer increases. This, as well as other unintended consequences, can adversely affect the operation of the transistor.

The leakage current, for example, may be reduced or eliminated by increasing the thickness of the gate dielectric layer (with respect to its thickness after being scaled down). However, unless the dielectric constant of the gate dielectric layer is increased, then this increase in thickness will cause a decrease in gate capacitance (which is undesirable as the transistor is scaled down). Therefore, one potential solution to this problem is to replace the silicon dioxide (or other similar gate dielectric materials) with dielectric materials having a higher dielectric constant. Due to their higher dielectric constant (k), a thicker layer of such materials may be used to reduce the leakage current while providing the same gate capacitance and other benefits as a thinner layer of silicon dioxide.

Examples of such high-k materials that may be used for the gate dielectric layer may include, but are not limited to, zirconium silicon oxides, hafnium silicon oxides, aluminum oxide, yttrium oxide, yttrium-silicon-oxides, lanthanum oxide, lanthanum silicon oxides, zirconium aluminate, hafnium aluminate, lanthanum aluminate, aluminum nitride, tantalum oxide, titanium oxide, zirconium oxide, hafnium oxide, zirconium oxynitride, hafnium oxynitride, zirconium silicon oxynitride, hafnium silicon oxynitride, and other metal silicon oxynitrides and metal aluminum oxynitrides. Any other appropriate high-k dielectric materials may also be used. It will be appreciated that high-k dielectric materials are generally understood to mean materials having a dielectric constant higher than that of silicon dioxide (which is about 3.9).

Unlike silicon dioxide, these high-k materials typically must be deposited instead of being grown on the substrate. Such deposited films are often not stoichiometric and, as such, may have defects and/or impurities associated therewith that affect their electrical properties. In order to remove these impurities and/or to densify and fully oxidize a high-k gate dielectric layer, the layer is typically annealed. It will be appreciated that annealing in accordance with one or more aspects of the present invention can occur at any one or more appropriate stages of the fabrication process, such as before and/or after the creation of the source/drain regions.

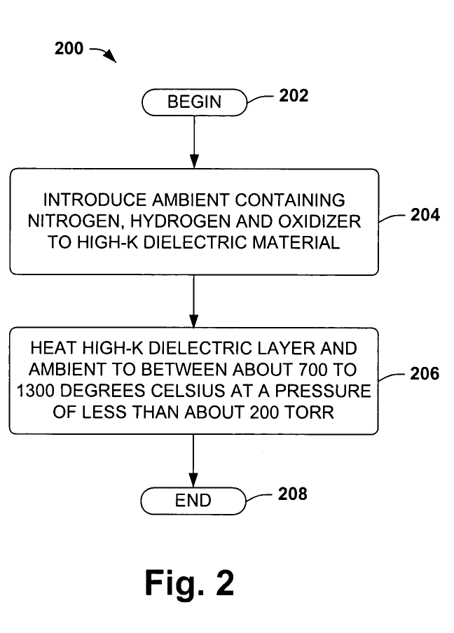

Accordingly, FIG. 2 is a flow diagram illustrating an exemplary method 200 for annealing a high-k dielectric material in accordance with one or more aspects of the present invention. Although the method 200 is illustrated and described herein as a series of acts or events, it will be appreciated that the present invention is not limited by the illustrated ordering of such acts or events. For example, some acts may occur in different orders and/or concurrently with other acts or events apart from those illustrated and/or described herein. In addition, not all illustrated steps may be required to implement a methodology in accordance with one or more aspects of the present invention. In addition, the methods according to the present invention may be implemented in association with the formation and/or processing of structures illustrated and described herein as well as in association with other structures not illustrated.

Beginning at 202, the method 200 comprises bringing together the high-k dielectric material and the ambient. By way of example, at 204 the ambient may be introduced into a processing chamber wherein the high-k material resides. Then, at 206 the ambient and high-k dielectric is heated to about 700 to 1300 degrees Celsius at a pressure of under about 200 Torr. The process then ends and the high-k dielectric can proceed to further processing stages, such as patterning in the formation of one or more transistors.

According to one or more aspects of the present invention, the ambient utilized comprises a single chemistry of nitrogen and hydrogen, such as ammonia (NH₃), and an oxidizer (e.g., O, N₂O, NO, water vapor (H₂O)) that promotes desired annealing (e.g., purification, oxidation and densification of the high-k dielectric). Under these conditions nitrogen can be introduced into the dielectric, the hydrogen can react with unwanted impurities forming volatile species, and the oxygen reacts with the dielectric to decrease point defects such as oxygen vacancies. The hydrogen can also act as a passivant of defects that are not fixed by oxidation. The presence of nitrogen and hydrogen also enables the annealing process temperature to be increased. An increase in processing temperature yields a corresponding increase in the film densification as well as a reduction in the number of defects.

It will be appreciated that any appropriate proportions of ammonia and oxygen may be used in the annealing process according to one or more aspects of the present invention. By way of example, ammonia may initially be introduced to the high-k material followed by oxygen to mitigate the likelihood of crystallization of the high-k material at higher temperatures. By way of further example, a greater concentration of an oxidizer may be needed if some nitrogen is already present in the high-k material. Similarly, more ammonia may need to be added if additional nitrogen is required. Also, additional chemistries, such as hydrogen and/or argon can be added to the ambient for dilution purposes to alter (e.g., broaden) the suitable temperature range for the process.

It will be appreciated, however, that as the proportion of oxygen increases, the annealing process can become more aggressive, causing both the oxidation of the gate dielectric layer and the formation of interfacial lower-k dielectrics to increase. Consequently, the proportion of oxygen may be chosen for a particular application by balancing the desire for rapid oxidation against unwanted interfacial growth.

Additionally, while annealing may be performed at a relatively lower temperature (e.g., of less than approximately 600 degrees Celsius) to prevent or reduce the growth of lower-k dielectric materials and to reduce crystallization of the gate dielectric layer (which is advantageous since crystallization can result in defect formation at the grain boundaries), lower temperatures also hamper the proper oxidation of the high-k gate dielectric layer. Annealing the gate dielectric material at higher temperatures of between about 700 to 1300 degrees Celsius according to one or more aspects of the present invention allows the high-k gate dielectric layer to be oxidized in a desired manner (e.g., to remove defects, such as OH, and H or any other unwanted specie that reacts with the ambient gas) while the inclusion of hydrogen still prevents or reduces the growth of interfacial lower-k dielectric materials.

It will be appreciated, however, that the actual anneal temperature can be chosen depending upon the oxidizer partial pressure and the need to avoid significant oxidation of the substrate to dielectric interface. The partial pressure is the portion of the total pressure attributable to a particular agent. Accordingly, the oxidizer partial pressure is the fraction of the oxidizer relative to the total pressure. Consequently, the anneal is preferably done at a relatively low pressure, such as below about 200 Torr, and even more preferably below about 20 Torr.

While not wishing to be tied to any particular theory, higher temperature anneals are thought to allow atoms to have more energy and move around more easily, and thus have better reactions and occupy more stable positions in the high-k dielectric layer. Consequently, fewer dangling bonds are left and the high-k material has a relatively greater density. At lower temperatures more defects may remain because there is less atomic mobility resulting in more frozen-in defects.

The low pressures disclosed herein also serve to mitigate the chance for unwanted exothermic reactions between the ammonia and oxidizer, particularly at the temperatures utilized. As such, the present invention allows the anneal to take place with a single chemistry, whereas conventionally multiple stages of annealing that utilize respective sets of the same or different chemistries would have to be utilized to achieve the desired outcome (e.g., adequate oxidation, defect passivation, densification, etc.).

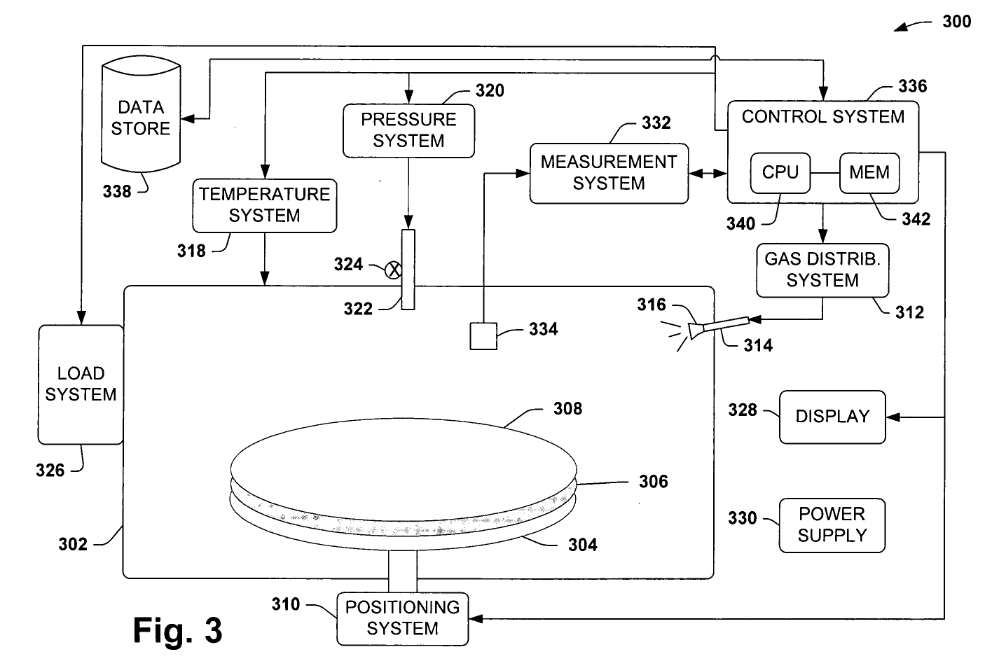

Referring now to FIG. 3, an exemplary system 300 suitable for implementing one or more aspects of the present invention is illustrated in schematic block diagram form. In particular, a process chamber 302 is depicted defined by a housing having a plurality of walls. The chamber 302 includes a support, such as may include a stage 304 (or chuck) operative to support (e.g. via vacuum or electrostatic techniques) a semiconductor substrate, such as a wafer 306 having a layer of high-k dielectric material 308 formed there-over.

The layer of high-k dielectric material 308 is suitable for use as a gate dielectric in a transistor, and is deposited, rather than grown, over the substrate 306. By way of example, such a layer of high-k dielectric material can be deposited by chemical vapor deposition (CVD), low pressure CVD (LPCVD), plasma enhanced CVD (PECVD), rapid thermal CVD (RTCVD), metal organic CVD (MOCVD), pulsed laser deposition (PLD), atomic layer deposition (ALD), physical vapor deposition (PVD) and/or molecular beam epitaxy (MBE) techniques, etc. A positioning system 310 is operatively connected to the support 304 for selectively maneuvering the wafer 306 into desired position(s) within the chamber 302.

A gas distribution system 312 is also operably coupled to the chamber 302 for selectively providing gaseous chemicals, such as ammonia (NH₃) and an oxidizer (e.g., O, N₂O, NO, water vapor (H₂O)) into the chamber at respective, times, concentrations, flow rates, quantities, etc. By way of illustration, the gas distribution system 312 includes a source of a gaseous medium (a vapor) of one or more chemicals that are to be directed into the chamber. The gas is provided into the chamber 302 through a conduit 314 that terminates in a nozzle 316. While, for purposes of brevity, a single conduit 314 and a single nozzle 316 are shown in FIG. 3, it is to be appreciated that any number of conduits, nozzles and/or other gas delivery mechanisms may be utilized in accordance with one or more aspects of the present invention. For example, a shower head type gas delivery mechanism can be implemented to more evenly provide chemicals into the chamber, which can facilitate more uniform chemical reactions.

A temperature system 318 is also provided for controlling the temperature within the processing chamber 302. By way of example, the temperature system 318 may include a horizontal and/or vertical furnace, graphite heaters, microwave units, tungsten halogen lamps, etc. Similarly, a pressure system 320 is included to selectively regulate the pressure within the chamber. The pressure system 320 may include, for example, one or more vent conduits 322 having valves 324 that may be selectively opened and/or closed to varying degrees to assist with regulating the pressure within the chamber 302.

The system 300 also may include a load system 326 operatively connected to the chamber 302 for loading and unloading substrates (e.g. wafers) into and out of the processing chamber. Such a load system 326 would typically be automated to load and unload wafers into the chamber at a controlled rate. The system further may include a display 328 for presenting a representation (e.g. graphical and/or textual) of one or more process conditions, such as interface thickness, temperature, pressure, gas flow rates, etc. A power supply 330 is also included to provide operating power to components of the system 300. Any suitable power supply (e.g. battery, line power) may be implemented with the present invention.

A measurement system 332 is included having one or more sensors 334 (e.g., thermocouples, RTDs, etc.) positioned within the chamber 302. The sensors 334 are operable to measure one or more selected processing conditions within the chamber 302, such as the temperature, pressure, chemical species within the chamber 302, etc. The measurement system 332 is operatively coupled to a control system 336 and sends data regarding measurements taken thereto. The control system 336 may in turn analyze the information received from the measurement system to discern whether the annealing process is proceeding as planned. Should the process be occurring other than as intended, the control system 336 can adapt the annealing process by providing appropriate control signals to the associated systems (e.g. gas distribution system 312, temperature system 318, pressure system 320).

A data store 338 is also included in the example shown in FIG. 3. Information obtained by the measurement system can be compared to data within the data store 338 regarding desired annealing conditions to generate feed forward/backward control data to control one or more components of the system 300. For example, the rate, concentration and/or mixture of gases distributed into the processing chamber may be selectively adjusted to achieve a desired anneal.

It is to be appreciated that the data store 338 can store data in data structures including, but not limited to one or more lists, arrays, tables, databases, stacks, heaps, linked lists and data cubes. Furthermore, the data store 338 can reside on one physical device and/or may be distributed between two or more physical devices (e.g. disk drives, tape drives, memory units). In the example shown in FIG. 3, the data store 338 is operatively coupled to the control system 336. The control system 336 may be employed in populating the data store 338 (e.g. via the measurement system 332 and sensors 334). Alternatively, the data store 338 may be directly connected to the measurement system 332 and sensors 334 so as to by-pass the control system 336 during population.

By way of example, the control system 336 includes a processor 340, such as a microprocessor or CPU, coupled to a memory 342. The processor 340 receives measured data from the measurement system 332. The processor 340 may also be operatively coupled to the positioning system 310, the gas distribution system 312, the temperature system 318, the pressure system 320, the load system 326 and/or the display 328. The control system 336, and more particularly the processor 340, may be programmed/and or configured in any suitable manner to control and operate the various components within the system 300 in order to carry out the various functions described herein.

The processor 340 may be any of a plurality of processors. The manner in which the processor 340 can be programmed to carry out the functions relating to the present invention will be readily apparent to those having ordinary skill in the art based on the description provided herein. It will be appreciated that the control system 336 may also provide for manually making adjustments to the conditions (e.g., temperature pressure) within the chamber, including the ambient introduced into the chamber 302, such as the composition thereof.

The memory 342 serves to store, among other things, program code that may be executed by the processor 340 for carrying out operating functions of the system as described herein. The memory 342 may include read only memory (ROM) and random access memory (RAM). The ROM contains among other code the Basic Input-Output System (BIOS) which controls the basic hardware operations of the system 300. The RAM is the main memory into which the operating system and application programs are loaded. The memory 342 also serves as a storage medium for temporarily storing information such as target dielectric values, coordinate tables, patterns against which observed data can be compared, and algorithms that may be employed in carrying out one or more aspects of the present invention, for example. As such, the memory 342 may comprise some or all of the data maintained within a data store 338 and may serve to fulfill some or all of the purposes of a data store. For mass data storage, the memory 342 may further include a hard disk drive. As a result, the system 300 provides for annealing a high-k dielectric in an ambient having a single chemistry of nitrogen and hydrogen, such as ammonia (NH₃), and an oxidizer to purify, oxidize and densify the high-k material, while mitigating the growth of a lower-k material at an interface of the high-k material and an underlying substrate. Additionally, the particular temperatures and pressures utilized within the system 300 serve to curtail the likelihood of an undesired exothermic reaction.

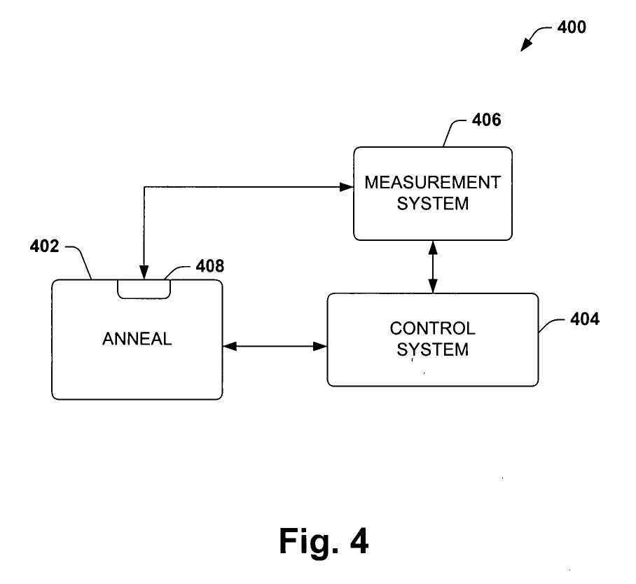

FIG. 4 is a schematic block diagram illustrating another exemplary system 400 suitable to implement a high-k dielectric annealing process in accordance with one or more aspects of the present invention. The process 402 may, for example, be included as part of a semiconductor fabrication process and be carried out within a fabrication chamber.

The system 400 includes a control system 404 for controlling operating characteristics of the process 402. The operating characteristics associated with the process 402 may include, for example, the temperature, concentration/species of gases within the process, pressure associated with the process, and timing parameters associated with the process. The control system 404 may selectively adjust one or more operating parameters of the process 402 based on sensed operating conditions associated with the process 402.

As such, a measurement system 406 is operatively associated with the process 402 to measure operating characteristics of the process 402. That is, the measurement system 406 includes one or more monitoring portions 408, which may be positioned at one or more locations within the processing chamber. The measurement system 406 may, for example, include a plurality of sensors scattered about the chamber to sample the annealing ambient composition and/or concentration at various areas within the chamber, as well as the pressure and/or temperature at various areas within the chamber. In this manner, variations within the chamber can be detected and such process drift can be quickly addressed and remedied. It will be appreciated that any suitable measurement configuration (e.g. number, type, arrangement of sensors) may be utilized in accordance with one or more aspects of the present invention.

The measurement system 406 is operatively coupled to the control system 404 to provide one or more signals indicative of measured conditions to facilitate adjusting one or more operating parameters of the fabrication process to achieve a desired result (e.g. a desired level of oxidation with concurrent mitigation of lower-k interfacial growth). The control system 404 may, for example, adjust gas flow rates/concentration, pressure, temperature, etc.

It is to be appreciated that the elements depicted and described herein in association with the accompanying figures and drawings are depicted with particular dimensions relative to one another (e.g., layer to layer dimensions and/or orientations) for demonstrative purposes and simplicity and ease of understanding, and that they may not be drawn to scale and that the actual dimensions of the elements may differ substantially from that shown and described herein. It is also to be appreciated that reference to substrate or semiconductor substrate as used herein can include a base semiconductor wafer (e.g., silicon, SiGe, or an SOI wafer) and any epitaxial layers or other type semiconductor layers formed thereover or associated therewith. Also, reference to the term exemplary herein is not meant to mean the best or pinnacle, but rather merely to an example.

Although the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

1. A method for annealing a layer of material having a high dielectric constant (high-k) formed over a semiconductor substrate, comprising:
introducing an ambient comprising hydrogen, nitrogen and an oxidizer to the substrate and layer of high-k material; and
heating the high-k dielectric layer to a temperature greater than 700 degrees Celsius while the gate dielectric layer is in the ambient, the ambient mitigating the formation of lower dielectric constant (lower-k) material between the high-k gate dielectric layer and the substrate.

2. The method of claim 1, wherein the ambient comprises ammonia (NH₃) and the oxidizer.

3. The method of claim 2, wherein the oxidizer includes at least one of O, N₂O, NO and H₂₀.

4. The method of claim 2, further comprising:
maintaining the high-k dielectric layer and ambient under a pressure of about 200 Torr.

5. The method of claim 2, further comprising heating the high-k dielectric layer to between about 700 to 1300 degrees Celsius.

6. The method of claim 2, further comprising:
maintaining the high-k dielectric layer and ambient under a pressure of about 20 Torr.

7. The method of claim 2, wherein the ammonia is initially introduced to the high-k material followed by the oxidizer to mitigate the likelihood of crystallization of the high-k material.

8. The method of claim 2, wherein a greater concentration of the oxidizer is included in the ambient when nitrogen is pre-existing within the high-k material.

9. The method of claim 2, further comprising:
adding argon to the ambient to broaden an acceptable temperature range.

10. A method for annealing a high dielectric constant (high-k) gate dielectric layer, comprising:
placing a wafer including one or more partially formed transistors in an ambient comprising hydrogen, nitrogen and an oxidizer, respective transistors comprising a high-k gate dielectric layer formed over a substrate; and
heating the high-k gate dielectric layer to a temperature greater than 700 degrees Celsius while the gate dielectric layer is in the ambient, the ambient mitigating the formation of lower dielectric constant (lower-k) material between the high-k gate dielectric layer and the substrate.

11. The method of claim 10, wherein the ambient comprises ammonia (NH₃) and the oxidizer.

12. The method of claim 11, wherein the oxidizer includes at least one of O, N₂O, NO and H₂₀.

13. The method of claim 11, further comprising:
maintaining the high-k dielectric layer and ambient under a pressure of about 200 Torr.

14. The method of claim 11, further comprising heating the high-k dielectric layer to between about 700 to 1300 degrees Celsius.

15. The method of claim 11, further comprising:
maintaining the high-k dielectric layer and ambient under a pressure of about 20 Torr.

16. A method for fabricating a transistor having a high dielectric constant (high-k) gate dielectric layer, comprising:
forming a high-k gate dielectric layer on a substrate; and
annealing the substrate and high-k gate dielectric layer,
the annealing comprising:
introducing an ambient comprising hydrogen, nitrogen and an oxidizer to the substrate and high-k gate dielectric layer;
heating the high-k dielectric layer to a temperature greater than 700 degrees Celsius while the gate dielectric layer is in the ambient, the ambient mitigating the formation of lower dielectric constant (lower-k) material between the high-k gate dielectric layer and the substrate.

17. The method of claim 16, wherein the ambient comprises ammonia (NH₃) and the oxidizer.

18. The method of claim 17, wherein the oxidizer includes at least one of O, N₂O, NO and H₂₀.

19. The method of claim 17, further comprising:
maintaining the high-k dielectric layer and ambient under a pressure of about 200 Torr.

20. The method of claim 17, further comprising heating the high-k dielectric layer to between about 700 to 1300 degrees Celsius.

21. The method of claim 17, further comprising:
maintaining the high-k dielectric layer and ambient under a pressure of about 20 Torr.
